(19) United States
(12) Patent Application Publication
(10) Pub. No.: US 2020/0303225 A1
(43) Pub. Date: Sep. 24, 2020

(54) METHOD OF MANUFACTURING SEMICONDUCTOR DEVICE

(71) Applicant: TOYOTA JIDOSHA KABUSHIKI KAISHA, Toyota-shi (JP)

(72) Inventor: Shuhei ICHIKAWA, Nisshin-shi (JP)

(73) Assignee: TOYOTA JIDOSHA KABUSHIKI KAISHA, Toyota-shi (JP)

(21) Appl. No.: 16/794,530

(22) Filed: Feb. 19, 2020

(30) Foreign Application Priority Data
Mar. 19, 2019 (JP) 2019-051304

(51) Int. Cl. H01L 21/673; H01L 21/02

(52) U.S. Cl. CPC H01L 21/67343; H01L 21/24; H01L 21/02266

(57) ABSTRACT

A method of manufacturing a semiconductor device may include: exposing a surface of a gallium oxide substrate to an acidic or alkaline chemical solution so as to increase a surface roughness of the surface; and forming an electrode on the surface having the increased surface roughness.

### TECHNICAL FIELD

The technology herein disclosed relates to a method of manufacturing a semiconductor device.

### BACKGROUND

In a method of manufacturing a semiconductor device described in Japanese Patent Application Publication No. 2009-081468, an electrode constituted of titanium is formed on a surface of a gallium oxide substrate. Japanese Patent Application Publication No. 2009-081468 describes that this configuration enables the electrode to be in ohmic contact with the gallium oxide substrate.

### SUMMARY

Even when an electrode is formed on a surface of a gallium oxide substrate as in Japanese Patent Application Publication No. 2009-081468, there may be a case where the electrode fails to exhibit ohmic properties. The present disclosure provides a new technology that enables an electrode to be in ohmic contact with a gallium oxide substrate.

The method disclosed herein relates to a method of manufacturing a semiconductor device. The method may comprise increasing a surface roughness of a surface of a gallium oxide substrate by exposing the surface to an acidic or alkaline chemical solution; and forming an electrode on the surface having the increased surface roughness.

By forming the electrode on the surface of the gallium oxide substrate that has the increased surface roughness as above, the electrode can be in ohmic contact with the gallium oxide substrate.

### BRIEF DESCRIPTION OF DRAWINGS

FIG. 1 is a flowchart showing a manufacturing method of an embodiment.

FIG. 2 is a plan view showing a pattern of an electrode for characteristic measurement.

FIG. 3 is a graph showing results of the characteristic measurement.

### DETAILED DESCRIPTION

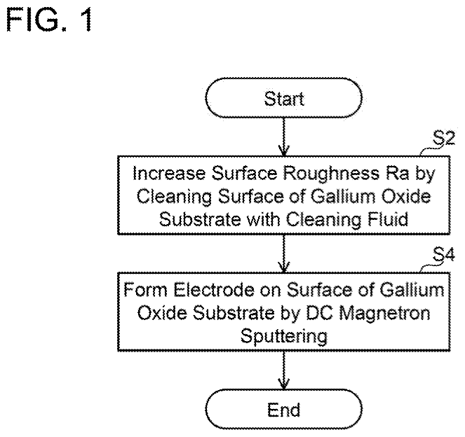

A method of manufacturing a semiconductor device of an embodiment will hereinafter be described. The manufacturing method of the present embodiment is characterized in its process of forming an electrode on a surface of a gallium oxide (Ga₂O₃) substrate, and thus the electrode-forming process will hereinafter be described. FIG. 1 is a flowchart showing the electrode-forming process.

Performed in step S2 is a cleaning step of cleaning a surface of a gallium oxide substrate with a cleaning fluid. Here, a hydrochloric acid peroxide mixture (i.e., an aqueous solution containing hydrochloric acid (HCl) and hydrogen peroxide (H₂O₂)) is used as the cleaning fluid. For example, a hydrochloric acid peroxide mixture containing 35 to 37 wt % of hydrochloric acid and 30 to 35.5 wt % of hydrogen peroxide (a hydrochloric acid peroxide mixture containing hydrochloric acid and hydrogen peroxide in a 5:2 volume ratio) can be used. As an example, in the cleaning step, the gallium oxide substrate can be dipped in the hydrochloric acid peroxide mixture at 85° C. for 10 minutes. When exposed to the hydrochloric acid peroxide mixture, the surface of the gallium oxide substrate is etched with the hydrochloric acid peroxide mixture. Consequently, a surface roughness Ra of the gallium oxide substrate increases. As an example, the gallium oxide substrate before the cleaning has the surface roughness Ra of 1.2 nm, whereas the gallium oxide substrate after the cleaning has the surface roughness Ra of 2.8 nm. The possible reason for such an increase in the surface roughness Ra of the gallium oxide substrate is that an etching rate depends on crystal orientations when the surface of the gallium oxide substrate is etched with the cleaning fluid, and hence the surface of the gallium oxide substrate is roughened accordingly. After cleaned with the hydrochloric acid peroxide mixture, the gallium oxide substrate is rinsed with ultrapure water, and is then dried by nitrogen gas being blown thereto.

Performed in step S4 is an electrode-forming step of forming an electrode on the surface of the gallium oxide substrate by sputtering. Here, an electrode constituted of titanium is formed on the surface of the gallium oxide substrate that has the surface roughness Ra increased in step S2. An example of a method that can be used for the sputtering is a DC magnetron sputtering method. In this case, the following conditions can be adopted for the sputtering: pure titanium can be used as a target; argon can be used as sputtering gas; heating of the gallium oxide substrate (stage heating) need not be performed; a gas pressure during electric discharge can be 0.1 to 1.0 Pa (e.g., 0.2 Pa); a density of input electric power to the target can be 0.1 to 50 W/cm² (e.g., 7.9 W/cm²); a maximum horizontal magnetic field at a surface of the target can be 200 to 1000 G; and a spacing between the target and the gallium oxide substrate can be 30 to 200 mm. Under such conditions, the electrode is formed on the surface of the gallium oxide substrate. For example, the electrode having a thickness of approximately 200 nm can be formed.

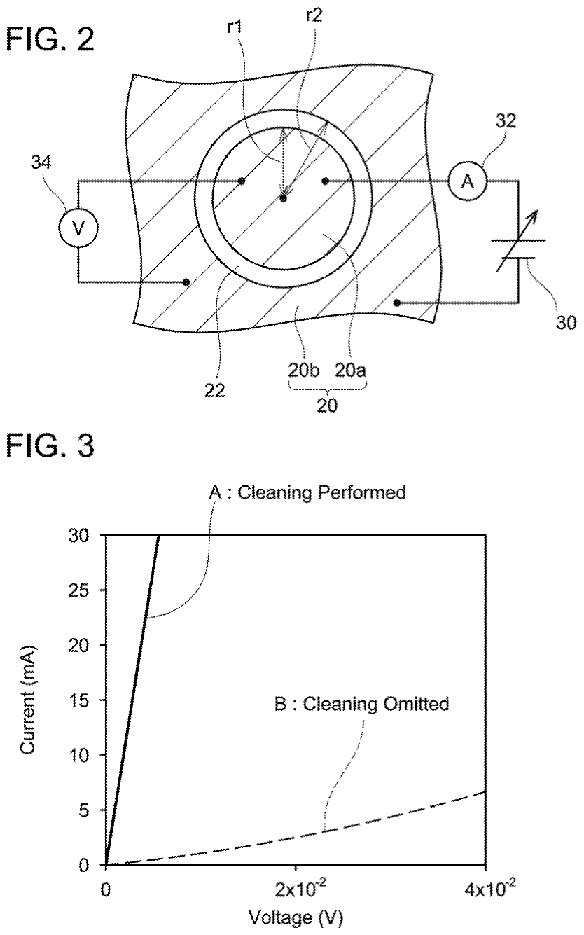

Next, results of characteristic evaluation of the electrode will be described. FIG. 2 shows an evaluation pattern for evaluating characteristics of the electrode. A region hatched with diagonal lines in FIG. 2 indicates an electrode 20. The electrode 20 is patterned by an annular clearance region 22. The electrode 20 is divided by the clearance region 22 into a first portion 20a and a second portion 20b. The clearance region 22 is free from the electrode 20, and the gallium oxide substrate is exposed therein.

The clearance region 22 is formed as follows. Firstly, a resist is applied by spin coating onto a surface of the electrode 20 where the clearance region 22 is to be formed. Next, a pattern having a shape of the clearance region 22 is transferred to the resist by ultraviolet exposure. Next, the resist is etched with a tetramethylammonium hydroxide aqueous solution (a TMAH aqueous solution) to remove a portion of the resist corresponding to the clearance region 22. Next, rite electrode 20 is etched with a mixed solution that contains 28 to 38 wt % of ammonia water and approximately 31 wt % of hydrogen peroxide, to remove a portion of the electrode 20 corresponding to the clearance region 22. The electrode 20 is there by patterned as shown in FIG. 2.

Current-voltage characteristics between the first portion 20a and the second portion 20b were measured by a four-terminal method. The measurement results will be described. An arbitrary current was flown by a power source 30 from the first portion 20a to the second portion 20b via the gallium oxide substrate to measure the flowing current by an ammeter 32 and measure a voltage between the first portion 20a and the second portion 20b by a voltmeter 34. FIG. 3 shows the measurement results. FIG. 3 shows current-voltage characteristics that were measured for each of a case where the cleaning step (step S2) was performed and then the electrode-forming step (step S4) was performed to form the electrode 20 as in FIG. 1 (cleaning performed: a graph A) and a case where the electrode-forming step (step S4) was performed but the cleaning step (step S2) was not performed to form the electrode 20 (cleaning omitted: a graph B). The measurement results of FIG. 3 show measurement results obtained in a case where the clearance region 22 had an inner diameter r1 (see FIG. 2) of 240 μm and an outer diameter r2 (see FIG. 2) of 260 μm.

As shown in FIG. 3, the graph A (cleaning performed) shows that the voltage and the current are linearly related, and the electrode 20 is in ohmic contact with the gallium oxide substrate. In the graph A, an electrical resistance is approximately 0.19Ω. On the other hand, the graph B (cleaning omitted) is curved and shows that the voltage and the current are not linearly related. Moreover, fewer current flow's between the electrode 20 and the gallium oxide substrate in the graph B than in the graph A. In the graph B (cleaning omitted), the electrode 20 is in Schottky contact with the gallium oxide substrate. As such, performing the electrode-forming step (step S4) after the cleaning step (step S2) enables the electrode 20 to be in ohmic contact with the gallium oxide substrate, and thus a contact resistance between the electrode 20 and the gallium oxide substrate can be reduced significantly. Increasing the surface roughness of the gallium oxide substrate by performing the cleaning step increases a contact area between the electrode 20 and the gallium oxide substrate, and the contact resistance between the electrode 20 and the gallium oxide substrate is thereby be decreased, by which they can be easily brought into ohmic contact.

As described above, the manufacturing method of the embodiment enables the electrode that is in ohmic contact with the gallium oxide substrate to be formed easily. In the manufacturing method herein disclosed, whether the gallium oxide substrate is heated or not after the electrode is formed may be arbitrarily determined. As in the above-mentioned embodiment, the electrode can be brought into ohmic contact with the gallium oxide substrate even without the gallium oxide substrate being heated after the electrode is formed. This eases temperature constraints in the manufacturing steps, such that the manufacturing steps can be constructed more freely. For example, before the electrode is formed, a film constituted of a heat-sensitive material (e.g., polyimide or the like) can be formed on the surface of the gallium oxide substrate. On the other hand, heating the gallium oxide substrate after the electrode is formed may be able to further reduce the contact resistance between the electrode and die gallium oxide substrate.

In the above-mentioned embodiment, the surface of the gallium oxide substrate is roughened by being etched with the hydrochloric acid peroxide mixture. However, the gallium oxide substrate may also be etched with another acidic aqueous solution. Therefore, an arbitrary acidic aqueous solution (e.g., phosphoric acid, nitric acid, hydrochloric acid, sulfuric acid, acetic acid, hydrogen peroxide, or an aqueous solution including at least one of them) may be used as the cleaning fluid in the cleaning step (step S2). Moreover, the gallium oxide substrate may also be etched with an alkaline aqueous solution. Therefore, an arbitrary alkaline aqueous solution (e.g., sodium hydroxide, potassium hydroxide, tetramethylammonium hydroxide, or an aqueous solution including at least one of them) may be used as the cleaning fluid in the cleaning step.

Moreover, in the above-mentioned embodiment titanium is used as a material for the electrode formed in the electrode-forming step (step S4). However, a material other than titanium may also be used.

Moreover, in the above-mentioned embodiment, the electrode is formed by the DC magnetron sputtering method in the electrode-forming step (step S4). However, in the electrode-forming step, the electrode may also be formed by another sputtering method. Moreover, in the electrode-forming step, the electrode may also be formed by a method other than the sputtering method, such as vapor deposition.

Some of the features described herein will be listed below. It should be noted that the respective technical elements are independent of one another, and are useful solely or in combinations.

In an example of the method of manufacturing a semiconductor device disclosed in the present disclosure, the chemical solution may comprise at least one of phosphoric acid, nitric acid, hydrochloric acid, sulfuric acid, acetic acid, hydrogen peroxide, sodium hydroxide, potassium hydroxide, and tetramethylammonium hydroxide. Also, the electrode may comprise titanium.

Also, in an example of the method of manufacturing a semiconductor device disclosed in the present disclosure, an increased amount of the surface roughness of the gallium oxide in the step of increasing the surface roughness may be equal to or more than 0.5 nm. Also, the surface roughness of the gallium oxide substrate after the step of increasing the surface roughness may be equal to or more than 2.5 nm.

While specific examples of the present disclosure have been described above in detail, these examples are merely illustrative and place no limitation on the scope of the patent claims. The technology described in the patent claims also encompasses various changes and modifications to the specific examples described above. The technical elements explained in the present description or drawings provide technical utility either independently or through various combinations. The present disclosure is not limited to the combinations described at the time the claims are filed. Further, the purpose of the examples illustrated by the present description or drawings is to satisfy multiple objectives simultaneously, and satisfying any one of those objectives gives technical utility to the present disclosure.

What is claimed is:

1. A method of manufacturing a semiconductor device, comprising:
increasing a surface roughness of a surface of a gallium oxide substrate by exposing the surface to an acidic or alkaline chemical solution; and
forming an electrode on the surface having the increased surface roughness.

2. The method of claim 1, wherein the chemical solution comprises at least one of phosphoric acid, nitric acid, hydrochloric acid, sulfuric acid, acetic acid, hydrogen peroxide, sodium hydroxide, potassium hydroxide, and tetramethylammonium hydroxide.

3. The method of claim 1, wherein the electrode comprises titanium.
